(19) United States
(12) Patent Application Publication
(10) Pub. No.: US 2014/0063930 A1
(43) Pub. Date: Mar. 6, 2014

(54) Processors and Systems with Drift-Tolerant Phase-Change Memory Data Storage

(71) Applicant: Being Advanced Memory Corporation, (US)

(72) Inventor: Aaron D. Willey, Burlington, VT (US)

(73) Assignee: Being Advanced Memory Corporation, Essex Junction, VT (US)

(21) Appl. No.: 13/869,243

(22) Filed: Apr. 24, 2013

Related U.S. Application Data
(60) Provisional application No. 61/694,223, filed on Aug. 28, 2012.
(60) Provisional application No. 61/694,224, filed on Aug. 28, 2012.
(60) Provisional application No. 61/694,225, filed on Aug. 28, 2012.

(51) Int. Cl. G11C 13/00

(52) U.S. Cl. CPC G11C 13/004
USPC 365/163

(57) ABSTRACT

Phase change memory arrays, subarrays, modules, and chips, as well as systems and devices in which phase change memory is used, wherein a reference corresponding to a pair of adjacent logical states (e.g., 0 and 1) can be generated by averaging outputs from a designated data-storing cell and a designated reference cell storing the logical complement to the logical state stored by the data-storing cell. By writing designated cells contemporaneously with words of cells that are configured to be written together, resulting references can closely track resistance changes in said words resulting from, e.g., drift and other time- and phase change material-dependent factors.

### CROSS-REFERENCE

Priority is claimed from U.S. Provisional Patent Applications 61/694,223, 61/694,224, and 61/694,225, all filed Aug. 28, 2012, and all hereby incorporated by reference.

### BACKGROUND

The present application relates to systems, devices and methods for memory access operations involving phase change memory units.

Note that the points discussed below may reflect the hindsight gained from the disclosed inventions, and are not necessarily admitted to be prior art.

Phase change memory (“PCM”) is a relatively new nonvolatile memory technology, which is very different from any other kind of nonvolatile memory. First, the fundamental principles of operation, at the smallest scale, are different: no other kind of solid-state memory uses a reversible PHYSICAL change to store data. Second, in order to achieve that permanent physical change, an array of PCM cells has to allow read, set, and reset operations which are all very different from each other. The electrical requirements of the read, set, and reset operations make the peripheral circuit operations of a PCM very different from those of other nonvolatile memories. Obviously some functions, such address decoding and bus interface, can be the same; but the closest-in parts of the periphery, which perform set, reset, and read operations on an array or subarray, must satisfy some unique requirements.

The physical state of a PCM cell's memory material is detected as resistance. For each selected cell, its bitline is set to a known voltage, and the cell's access transistor is turned on (by the appropriate wordline). If the cell is in its low-resistance state, it will sink a significant current from the bit line; if it is not, it will not.

Set and Reset operations are more complicated. Both involve heat. As discussed below, a “set” operation induces the memory material to recrystallize into its low-resistance (polycrystalline) state; a “reset” operation anneals the memory material into its high-resistance (amorphous) state.

Write operations (Set and Reset) normally have more time budget than read operations. In read mode a commercial PCM memory should be competitive with the access speed (and latency if possible) of a standard DRAM. If this degree of read speed can be achieved, PCM becomes very attractive for many applications.

The phase change material is typically a chalcogenide glass, using amorphous and crystalline (or polycrystalline) phase states to represent bit states.

A complete PCM cell can include, for example: a top electrode (connected to the bit line), a phase change material (e.g. a chalcogenide glass), a conductive pillar which reaches down from the bottom of the phase change material, an access transistor (gated by a word line), and a bottom connection to ground. The phase change material can extend over multiple cells (or over the whole array), but the access transistors are laterally isolated from each other by a dielectric.

FIG. 2A shows an example of a PCM element 2010. A top electrode 2020 overlies a phase change material 2030, e.g. a chalcogenide glass. Note that material 2030 also includes a mushroom-shaped annealed zone (portion) 2070 within it. (The annealed zone 2070 may or may not be present, depending on what data has been stored in this particular location.) The annealed zone 2070, if present, has a much higher resistivity than the other (crystalline or polycrystalline) parts of the material 2030.

A conductive pillar 2050 connects the material 2030 to a bottom electrode 2040. In this example, no selection device is shown; in practice, an access transistor would normally be connected in series with the phase change material. The pillar 2050 is embedded in an insulator layer 2060.

When voltage is applied between the top 2020 and bottom 2040 electrodes, the voltage drop will appear across the high-resistivity zone 2070 (if present). If sufficient voltage is applied, breakdown will occur across the high-resistivity zone. In this state the material will become very conductive, with large populations of mobile carriers. The material will therefore pass current, and current crowding can occur near the top of the pillar 2050. The voltage which initiates this conduction is referred to as the “snapback” voltage, and FIG. 2C shows why.

FIG. 2C shows an example of instantaneous I-V curves for a device like that of FIG. 2A, in two different states. Three zones of operation are marked.

In the zone 2200 marked “READ,” the device will act either as a resistor or as an open (perhaps with some leakage). A small applied voltage will result in a state-dependent difference in current, which can be detected.

However, the curve with open circles, corresponding to the amorphous state of the device, shows some more complex behaviors. The two curves show behaviors under conditions of higher voltage and higher current.

If the voltage reaches the threshold voltage Vₜₕ, current increases dramatically without any increase in voltage. (This occurs when breakdown occurs, so the phase-change material suddenly has a large population of mobile carriers.) Further increases in applied voltage above Vₜₕ result in further increases in current; note that this upper branch of the curve with hollow circles shows a lower resistance than the curve with solid squares.

If the applied voltage is stepped up to reach the zone 2150, the behavior of the cell is now independent of its previous state.

When relatively large currents are applied, localized heating will occur at the top of the pillar 2050, due to the relatively high current density. Current densities with typical dimensions can be in the range of tens of millions of Amperes per square cm. This is enough to produce significant localized heating within the phase-change material.

This localized heating is used to change the state of the phase-change material, as shown in FIG. 2B. If maximum current is applied in a very brief pulse 2100 and then abruptly stopped, the material will tend to quench into an amorphous high-resistivity condition; if the phase-change material is cooled more gradually and/or not heated as high as zone 2150, the material can recrystallize into a low-resistivity condition. Conversion to the high-resistance state is normally referred to as “Reset”, and conversion to the low-resistance state is normally referred to as “Set” (operation 2080). Note that, in this example, the Set pulse has a tail where current is reduced fairly gradually, but the Reset pulse does not. The duration of the Set pulse is also much longer than that of the Reset pulse, e.g. tens of microseconds versus hundreds of nanoseconds.

FIG. 2D shows an example of temperature versus resistivity for various PCM materials. It can be seen that each curve has a notable resistivity drop 2210 at some particular temperature. These resistivity drops correspond to phase change to a crystalline (or polysilicon) state. If the material is cooled gradually, it remains in the low resistivity state after cooling.

In a single-bit PCM, as described above, only two phases are distinguished: either the cell does or does not have a significant high-resistivity “mushroom cap” 2070. However, it is also possible to distinguish between different states of the mushroom cap 2070, and thereby store more than one bit per cell.

FIG. 2E shows an equivalent circuit for an “upside down” PCM cell 2010. In this example the pass transistor 2240 is gated by Wordline 2230, and is connected between the phase-change material 2250 and the bitline 2220. (Instead, it is somewhat preferable to connect this transistor between ground and the phase-change material.

FIG. 2F shows another example of a PCM cell 2010. A bitline 2220 is connected to the top electrode 2020 of the phase-change material 2250, and transistor 2240 which is connected to the bottom electrode 2030 of the PCM element. (The wordline 2230 which gates the vertical transistor 2240 is not shown in this drawing.) Lines 2232, which are shown as separate (and would be in a diode array), may instead be a continuous sheet, and provide the ground connection.

FIG. 2G shows an example of resistance (R) over time (t) for a single PCM cell following a single PCM write event at time t=0. The resistance curve 2400 for a cell which has been reset (i.e. which is in its high-resistance state) may rise at first, but then drifts significantly lower. The resistance curve 2410 for a cell in the Set state is much flatter. The sense margin 2420, i.e., the difference between set and reset resistances, also decreases over time. Larger sense margins generally result in more reliable reads, and a sense margin which is too small may not permit reliable reading at all. 2G represents the approximate behavior of one known PCM material; other PCM material compositions may behave differently. For example, other PCM material compositions may display variation of the set resistance over time.

The downwards drift of reset resistance may be due to, for example, shrinking size of the amorphous zone of the phase-change material, due to crystal growth; and, in some cells, spontaneous nucleation steepening the drift curve (possibly only slightly) due to introducing further conductive elements into the mushroom-shaped programmable region.

FIG. 2H shows an example of a processing system 2300. Typically, a processing system 2300 will incorporate at least some of interconnected power supplies 2310, processor units 2320 performing processing functions, memory units 2330 supplying stored data and instructions, and I/O units 2340 controlling communications internally and with external devices 2350.

FIG. 2I shows an example of a PCM single ended sensing memory. Two different PCM cells 2400 on different ends of a sense amplifier can be selected separately. Selected elements 2410 are separately sensed by a single-ended sense amplifier 2420.

FIG. 2J shows an example of a known PCM single ended sense amplifier 2500. Generally, in a single ended sense amplifier, a cell read output conducted by a selected bitline BLB is compared against a reference current to provide a digital output OUT. When the PRECHARGE signal turns on transistor 2530, voltage V04 (e.g., 400 mV) precharges the bitline BLB. After precharge ends, the READ signal turns on transistor 2550. Transistor 2550 is connected, through source follower 2560 and load 2580, to provide a voltage which comparator 2600 compares to Voltage_REF, to thereby generate the digital output OUT.

A variety of nonvolatile memory technologies have been proposed over recent decades, and many of them have required some engineering to provide reference values for sensing. However, the requirements and constraints of phase-change memory are fundamentally different from those of any other kind of nonvolatile memory. Many memory technologies (such as EEPROM, EPROM, MNOS, and flash) test the threshold voltage of the transistor in a selected cell, so referencing must allow for the transistor's behavior. By contrast, phase-change memory simply senses the resistance of the selected cell. This avoids the complexities of providing a reference which will distinguish two (or more) possibilities for an active device's state, but does require detecting a resistance value, and tracking external variations (e.g. temperature and supply voltage) which may affect the instantaneous value of that resistance.

The possibility of storing more than one bit of data in a single phase-change material has also been suggested. Phase-change memories implementing such architectures are referred to here as “multibit” PCMs. If the “Set” and/or “Reset” operations can be controlled to produce multiple electrically distinguishable states, then more than one bit of information can be stored in each phase-change material location. It is known that the current over time profile of the Set operation can be controlled to produce electrically distinguishable results, though this can be due to more than one effect. In the simplest implementation, shorter anneals—too short to produce full annealing of the amorphous layer—can be used to produce one or more intermediate states. In some materials, different crystalline phases can also be produced by appropriate selection of the current over time profile. However, what is important for the present application is merely that electrically distinguishable states can be produced.

For example, if the complete layer of phase-change material can have four possible I/V characteristics, two bits of information can be stored in each cell—IF the read cycle can accurately distinguish among the four different states.

(The I/V characteristics of the cells which are not in the fully Set state are typically nonlinear, so it is more accurate to distinguish the states in terms of current flow at a given voltage; resistance is often used as a shorthand term, but implies a linearity which may not be present.)

In order to make use of the possible multibit cell structures, it is necessary to reliably distinguish among the possible states. To make this distinction reliably, there must be some margin of safety, despite the change in characteristics which may occur due to history, manufacturing tolerances, and environmental factors. Thus the read architecture of multibit PCMs is a far more difficult challenge it is for PCMs with single-bit cells.

### SUMMARY

The present application discloses surprising new approaches to phase-change memory (PCM) arrays, subarrays, cores, and chips, as well as logic chips and systems in which PCM is used. Read reference values are generated from a (possibly weighted) average of the outputs of a specific column of data cells, and an additional column of reference cells which are always complementary to the cells of the specific column. Since the cells of the reference column are written exactly as often as the data cells of the specific column, so the combined outputs closely tracks drift and variation of the PCM cells on the same wordline.

### BRIEF DESCRIPTION OF THE DRAWINGS

The disclosed inventions will be described with reference to the accompanying drawings, which show important sample embodiments and which are incorporated in the specification hereof by reference, wherein:

FIG. 1A shows an example of a PCM memory.

FIG. 1B shows an example of logical states stored in a PCM memory.

FIG. 1C shows an example of a PCM memory.

FIG. 2A shows an example of a PCM element.

FIG. 2B shows an example of PCM bit line signals.

FIG. 2C shows an example of voltage versus current in a PCM material.

FIG. 2D shows an example of temperature versus resistance in a PCM material.

FIG. 2E shows an example of a PCM cell.

FIG. 2F shows an example of a PCM cell.

FIG. 2G shows an example of resistance over time for a PCM cell.

FIG. 2H shows an example of a processing system.

FIG. 2I shows an example of a PCM single ended sensing memory.

FIG. 2J shows an example of a known PCM single ended sense amplifier.

FIG. 3 shows an example of a PCM memory.

FIG. 4 shows an example of a PCM memory.

FIG. 5 shows an example of a sense amplifier.

FIG. 6A shows an example of a PCM memory.

FIG. 6B shows an example of logical states stored in a PCM memory.

FIG. 6C shows an example of a PCM memory.

FIG. 7 shows an example of a processing system.

### DETAILED DESCRIPTION OF SAMPLE EMBODIMENTS

The numerous innovative teachings of the present application will be described with particular reference to presently preferred embodiments (by way of example, and not of limitation). The present application describes several inventions, and none of the statements below should be taken as limiting the claims generally.

The present application discloses a new way to generate a read reference for phase change memory. This architecture generally avoids the need for coarse trimming. The reference comprises a boundary, or switchover point, between values that will be discriminated by a sense amplifier as a “0”, and values that will be discriminated as a “1”. By using PCM cell pairs (“reference cells”), each pair storing one “0” and one “1” state in single-bit PCM, applying the same voltage across both members of a pair, and using some ratio of the total current generated as a reference, the reference can be reliably matched to other PCM cells in the memory.

PCM materials generally exhibit an inherent “resistance drift” associated with each storage cell. Typically, drift increases during service at a predictable time-dependent rate characteristic of a corresponding PCM material, with the drift versus time curve starting from (t=0) when a PCM phase change (e.g., a write) occurs. By writing reference cells contemporaneously with a corresponding word of PCM memory, drift characteristics of the reference cells can be matched to drift characteristics of the co-written storage cells.

The cells used to generate the reference track the resistance drift and resistance temperature response characteristics of cells in a corresponding word. Therefore, the generated reference can be guaranteed to be between actual PCM cell outputs corresponding to “0” and “1” logical states from cells in the corresponding word. Because outputs from the corresponding word that correspond to a “0” logical state will always fall on one side of the reference, and outputs from the corresponding word that correspond to a “1” state will always fall on the other side of the reference, the reference can be used to reliably distinguish between “0” and “1” outputs.

If PCM read output values are viewed as currents, then for a read output corresponding to a high resistance PCM cell, Ipcm0, a read output corresponding to a low resistance PCM cell Ipcm1, and a reference signal I_Reference, the reference should obey the following inequality in order to distinguish Ipcm0 from Ipcm1: Ipcm0<I_Reference<Ipcm1. Margins between Ipcm0 and I_Reference, and between I_Reference and Ipcm1, can be targetted to optimize read quality (e.g., reliability).

For example, a reference may be generated by taking an average for a single pair of (2) reference cells, comprising 2 total reference cells, where Ipcm0 is the output current for a PCM cell in a logical “0” state, and Ipcm1 is the output current for a PCM cell in a logical “1” state,

$$Reference Current = \frac{Ipcm 0 + Ipcm 1}{2} . \qquad Equation 1$$

A weighted average can also be used as a reference. A weighted average may be used, for example, to compensate for greater drift or more sensitive temperature response in one PCM logical state than the other. For example, with a and b as respective weights,

$$Reference Current = \frac{a * Ipcm 0 + b * Ipcm 1}{2} . \qquad Equation 2$$

In some embodiments, multiple pairs of reference cells are used in order to obtain a more accurate result, preferably with the same voltage across all reference cells used to generate a single reference. As the number of reference cell pairs increases, reference accuracy increases. In this case, a reference is generated by taking a ratio (e.g., a weighted or unweighted average) of the summed outputs of corresponding reference cells. For a reference current generated from an average for n/2 pairs of reference cells (such that n/2 is an integer), comprising n total reference cells,

$$Reference Current = \frac{Ipcm 0 + Ipcm 1}{n} . \qquad Equation 3$$

In some embodiments, where multiple pairs of reference cells are used to obtain a more accurate result, and a weighted average is used,

$$Reference Current = \frac{a * Ipcm 0 + b * Ipcm 1}{n} . \qquad Equation 4$$

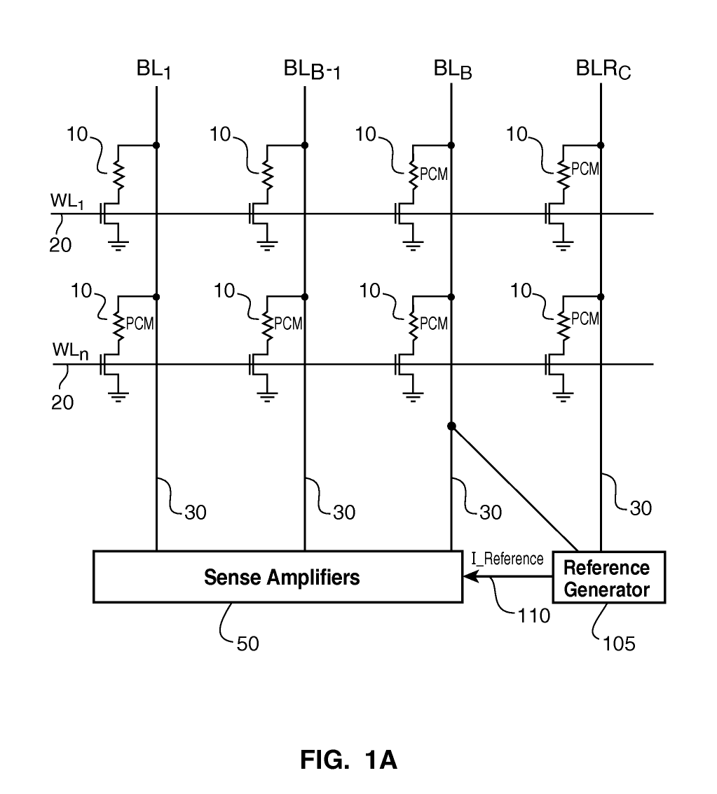

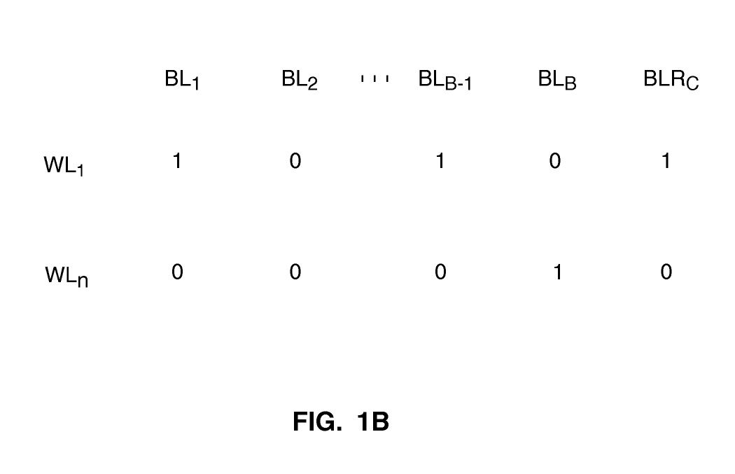

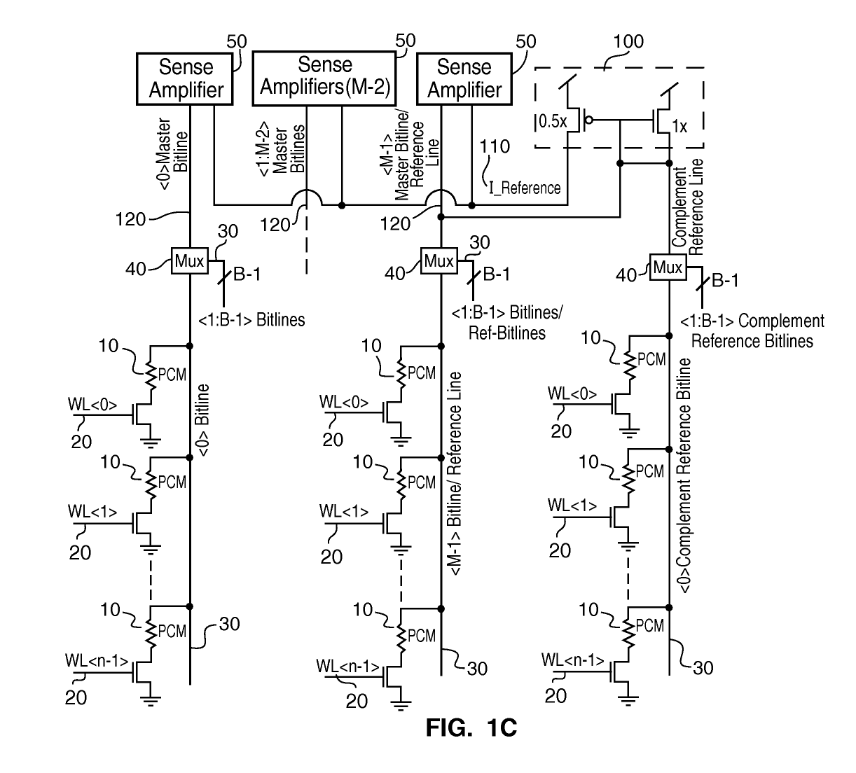

FIG. 1A shows an example of a PCM memory. In embodiments as shown in FIG. 1A, PCM cells 10 are accessed by n wordlines 20 (numbered WL₁ to WLₙ); B data-storing bitlines 30 (numbered BL₁ to BL_{B}), one of which doubles as a reference bitline 30, here BL_{B}; and a reference complement bitline 30 (BLR_{C}). Reference cells 10 in the reference complement bitline 30 BLR_{C} store logical complements (“0” and “1” are each others' complements) of the logical states stored by the corresponding data-storing/reference cells 10 in the dual-purpose data-storing/reference bitline 30 BL_{B}.

In FIG. 1A, a word is accessed by a wordline 20 and bitlines 30 BL₁ to BL_{B}. A PCM cell 10 is accessed by activating the corresponding wordline 30 and bitline 20. The data-storing bitlines 30 are sensed by Sense Amplifiers 50 using a reference 110 (I_Reference) generated by a Reference Generator 105. When a word is read by activating a wordline 20—for example, WL₁—and multiple corresponding data-storing bitlines 30, BLR_{C} is also activated. The outputs of the data-storing/reference cell 10 activated by WL₁ and BL_{B}, and of the reference complement cell 10 activated by WL₁ and BLR_{C}, are used by the Reference Generator to generate a reference 110. The reference 110 is then used to read the outputs of the data-storing cells 10 activated by WL₁ and BL₁ through BLₙ.

Also, when a word of data-storing cells 10 corresponding to a wordline WLₖ are written, the reference complement cell 10 accessed by WLₖ and BLR_{C} is written with the complement of logical state stored by the data-storing/reference cell 10 accessed by WLₖ and BL_{B}, so that the reference complement cell 10 approximately perfectly tracks the drift characteristics of the corresponding data-storing word.

FIG. 1B shows an example of logical states stored in a PCM memory. PCM cells 10 storing logical states (“0”s and “1”s) are accessed by corresponding wordlines 20 (WL₁ though WLₙ) and bitlines 30 (BL₁ through BL_{B}), and are interpreted using a reference 110 generated using outputs of reference cells 10 accessed by a data-storing/reference bitline 30 (BL_{B}) and a reference complement bitline (BL_{C}).

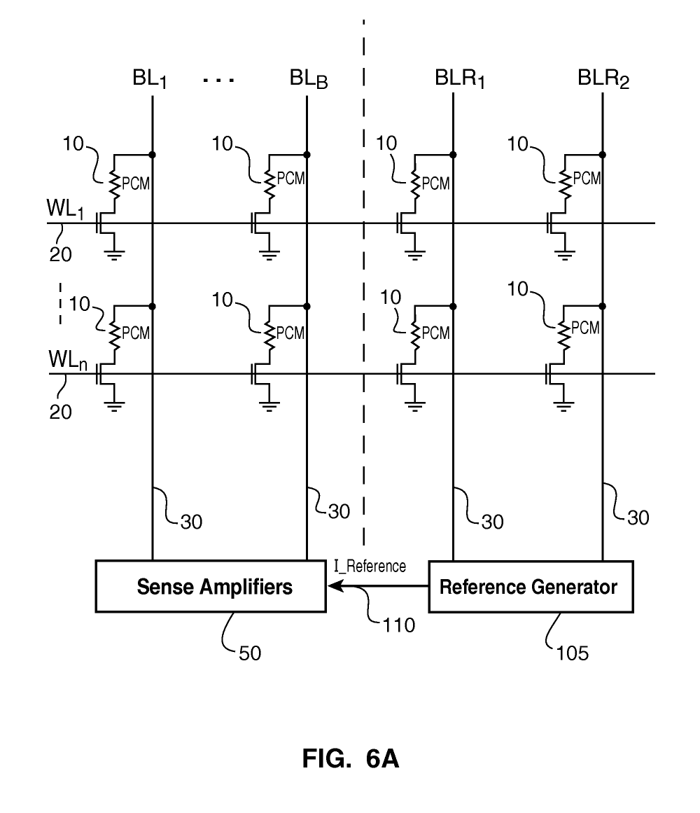

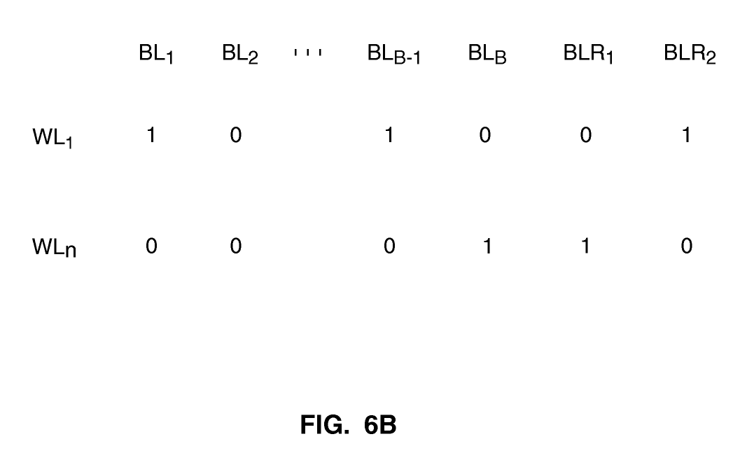

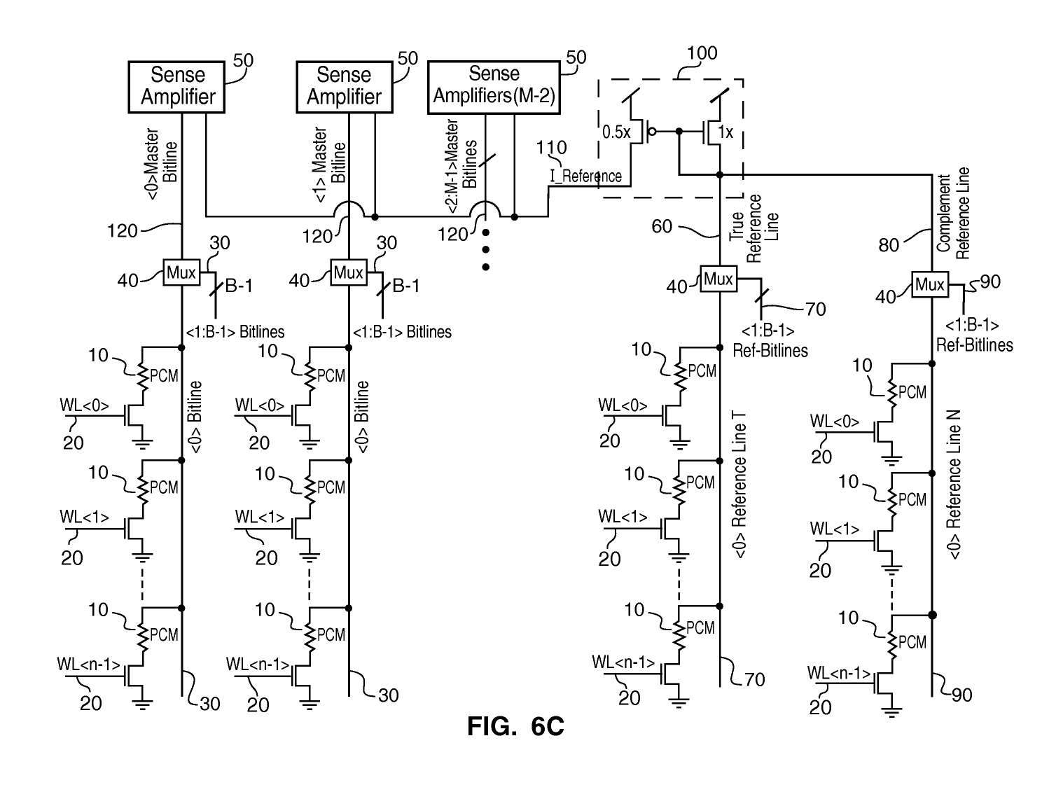

FIG. 1C shows an example of a PCM memory. In embodiments as shown in FIG. 1C and FIG. 6C, n equals (only for FIGS. 1C and 6C) the number of PCM cells 10 accessible by a given bitline 20, 60, 70 and the number of wordlines 30 accessing said cells 10 (numbered 0 to n−1); B equals the number of bitlines 30 multiplexed (muxed) by a single multiplexer 40 (mux) and, for data-storing (non-reference) bitlines 20, sensed by a given sense amplifier 50 (numbered 0 to B−1); and M is the number of sense amplifiers 50 and also the number of muxes 40 configured to mux bitlines 30 accessing data-storing (non-reference) cells 10 (numbered 0 to M−1). Mux 40 outputs correspond to outputs of accessed cells 10. Wordlines 20 WL<index-n> and bitlines 30 <index-B>Bitline access corresponding PCM cells 10.

In embodiments as shown in FIG. 1C, for a word of data-storing cells 10, one of the data-storing cells 10 doubles as a reference cell 10 using whatever value is written in the cell 10, and a complement reference cell 10 is written with the complement (i.e., a logical “0” complements a logical “1”, and vice versa) of the value written in the data-storing/reference cell 10. This means that, for single-bit (two logical states per memory element) PCM, a single mux 40 worth of dedicated Complement Reference Bitlines 150, corresponding to a single Complement Reference Line 160 mux 40 output, is sufficient—in combination with a corresponding data-storing/reference output (in FIG. 1, <M>Master Bitline/Reference 120)—to generate a reference 110 when summed and averaged using a current multiplier 100. (More complement reference cells 10, paired with the same or different data-storing cells 10, can be used to increase reference 110 reliability). This can mean a significant memory-area savings, which can be dedicated to increased memory density or recovered for other purposes.

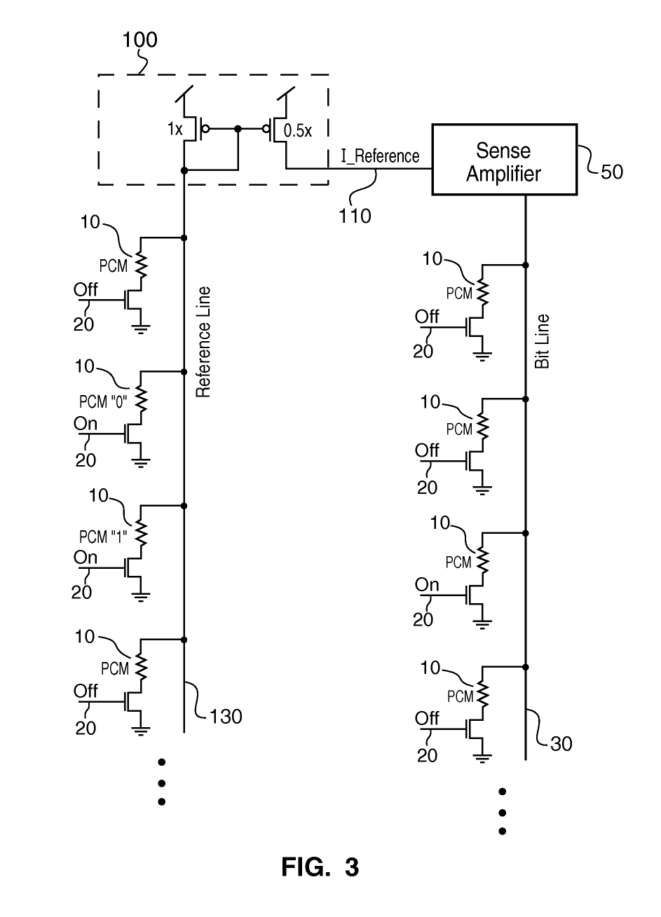

FIG. 3 shows an example of a PCM memory. Here, a PCM reference cell 10 storing a “0” logical state 10 and a PCM reference cell 10 storing a “1” logical state are located on a single reference bitline 130 (“Reference Line”), and are accessed by turning their corresponding wordlines 20 and the Reference Line 130 “On”. The output currents from the paired reference cells 10 are averaged by a current multiplier 100 with a ratio of 0.5 (½), and the resulting reference current 110 (“I_Reference”) is fed into a sense amplifier 50 configured to sense a corresponding bitline 30. I_Reference 110 for this case can be calculated as shown in Equation 1.

On a bitline 30 comprising data-storing cells, a PCM cell 10 that is part of a word written contemporaneously with corresponding reference cells 10 is also accessed by turning its wordline 20 and bitline 30 “On”. The resulting output current is compared by the Sense Amplifier 50 to I_Reference 110. If the data-storing cell 10 output current is higher than I_Reference 110, then the data-storing cell 110 is detected to be storing a “1”; if the data-storing cell 10 output current is lower than I_Reference 110, then the data-storing cell 10 is detected to be storing a “0”.

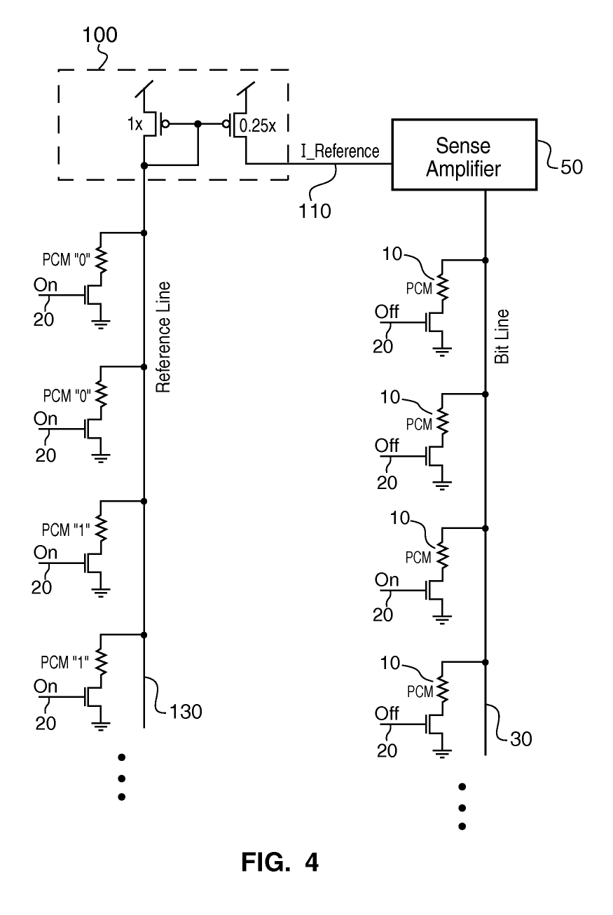

FIG. 4 shows an example of a PCM memory. Here, two pairs of reference cells 10 are accessed by activating their corresponding wordlines 20 and Reference Line 130, their output currents are summed—they are connected to the same Reference Line 130—and the resulting current is averaged by the current multiplier 100. As shown, because two (2) pairs of high and low resistance (“0” and “1” logical states) reference cells 10 are activated contemporaneously, n is 4 and the summed current is divided by 4 (multiplied by 0.25) as in Equation 3. The accessed data-storing cell 10 (the data-storing cell 10 on Bit Line 30 with an “On” wordline 20) is then compared to I_Reference 110 by the sense amplifier 50 to determine what logical state is stored by the data-storing cell 10.

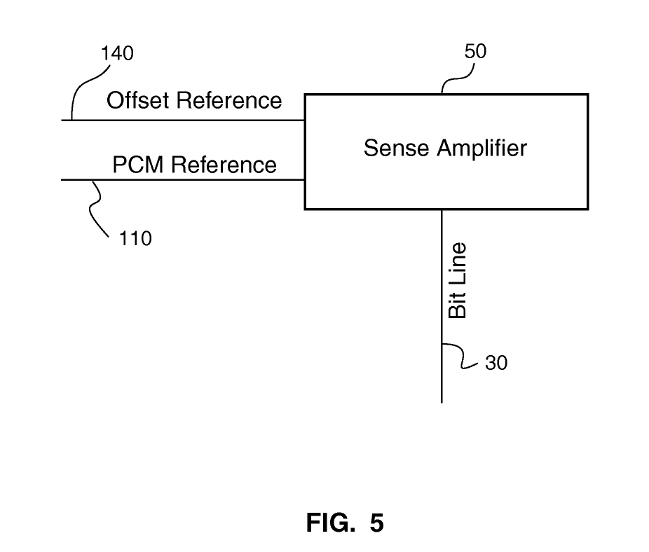

FIG. 5 shows an example of a sense amplifier 50. Here, an Offset Reference 140—a fine trim, generally preset, used to fine-tune the reference, and unsuitable for use by itself as a reference—appears as an additional input to the Sense Amplifier 50, where it will be used to modify the PCM Reference 110 generated from reference cells 10 prior to comparison between the data-storing cell 10 output and the reference 110.

FIG. 6A shows an example of a PCM memory. In embodiments as shown in FIG. 6A, PCM cells 10 are accessed by n wordlines 20 (numbered WL₁ to WLₙ), B data-storing bitlines 30 (numbered BL₁ to BL_{B}) and two reference bitlines 30 (BLR₁ and BLR₂). In FIG. 6A, a word is accessed by a wordline 20 and bitlines 30 BL₁ to BL_{B}. A PCM cell 10 is accessed by activating the corresponding wordline 20 and bitline 30. The data-storing bitlines 30 are sensed by Sense Amplifiers 50 using a reference 110 (I_Reference) generated by a Reference Generator 105. When a word is read by activating a wordline 20—for example, WL₁—and multiple corresponding data-storing bitlines 30, BLR₁ and BLR₂ are also activated. The outputs of the reference cells 10 activated by WL₁, BLR₁ and BLR₂ are used by the Reference Generator 105 to generate a reference 110. The reference 110 is then used to read the outputs of the data-storing cells 10 activated by WL₁ and BL₁ through BLₙ.

Also, when a word of data-storing cells 10 corresponding to a wordline 20 WLₖ are written, the reference cells 10 accessed by WLₖ, BLR₁ and BLR₂ are written with complementary logical states (e.g., “0” and “1”), so that the reference cells 10 approximately perfectly track the drift characteristics of the corresponding data-storing word.

FIG. 6B shows an example of logical states stored in a PCM memory. PCM cells 10 storing logical states (“0”s and “1”s) are accessed by corresponding wordlines 20 (WL₁ though WLₙ) and bitlines 30 (BL₁ through BL_{B}), and are interpreted using a reference 110 generated using outputs of reference cells 10 accessed by reference bitlines 30 (BLR₁ and BLR₂).

FIG. 6C shows an example of a PCM memory. In embodiments as shown in FIG. 6C, there is a True Reference Line 60, comprising the output of a mux 40 that muxes reference bitlines accessing cells 10 storing logical “1” 70 (<index-B>Reference Line T), and a Complement Reference Line 80, comprising the output of a mux 40 that muxes reference bitlines accessing cells 10 storing logical “0” 90 (<index-B>Reference Line N). Reference cells 10 corresponding to the True Reference Line 60 are paired with cells 10 corresponding to the Complement Reference Line 80.

When data-storing cells 10 in a word are accessed by activating corresponding wordlines 20 and bitlines 30, one or more pairs of reference cells 10 corresponding to said word on one or more Reference Lines T 70 and one or more Reference Lines N 90 are also accessed. The read outputs of the accessed reference cells 10 are summed together and averaged by a current multiplier 100 to produce a reference I_Reference 110. The reference 110 is used by the sense amplifiers to interpret <0:M−1>Master Bitline 120 signals—i.e., mux outputs—into corresponding logical states stored by the accessed cells 10. Master Bitline 120 signals are mux 40 outputs corresponding to outputs from accessed cells 10.

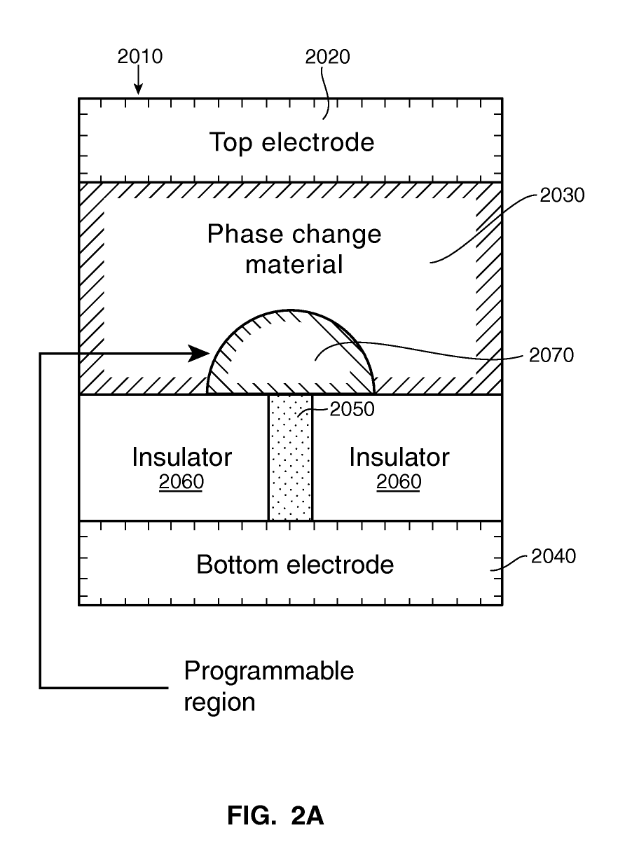

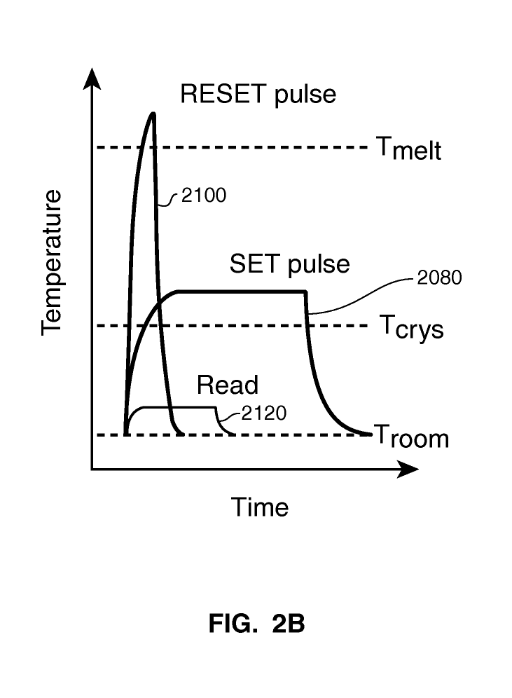

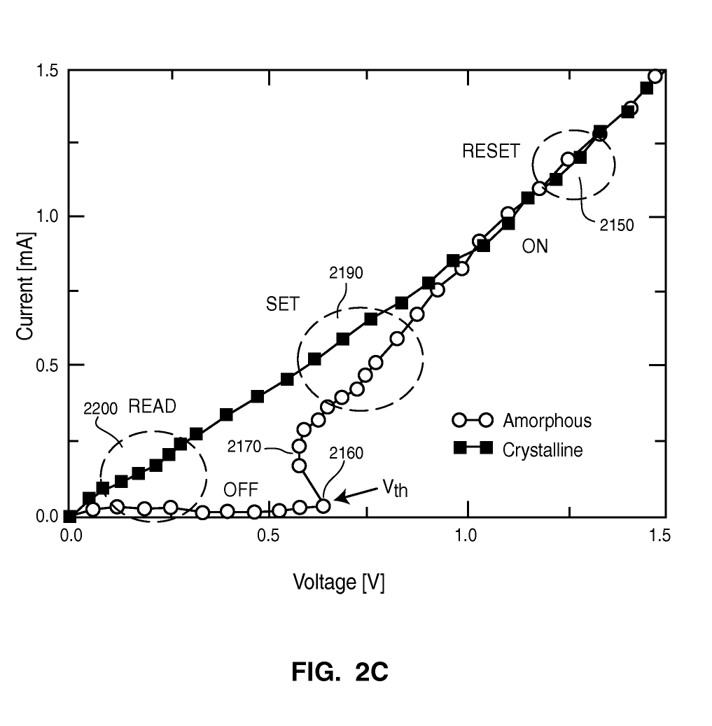

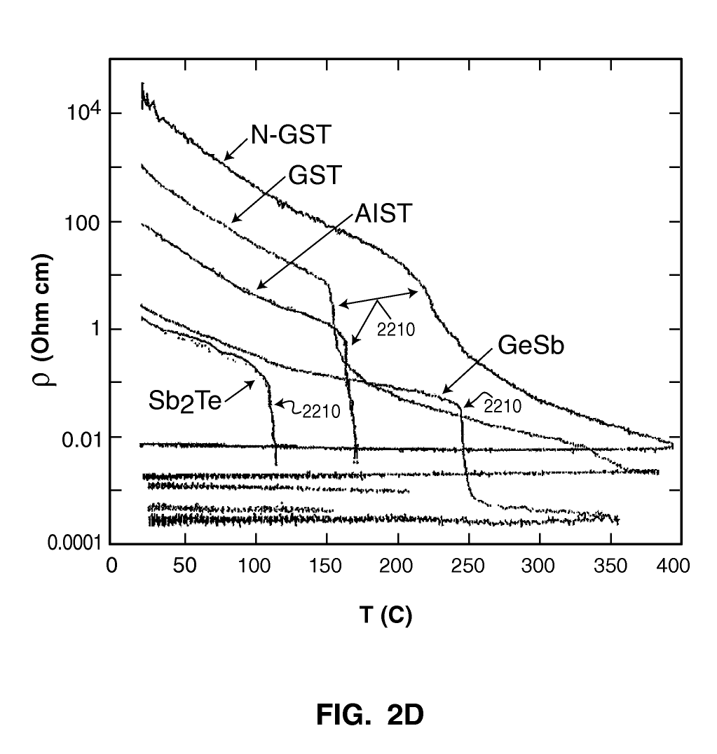

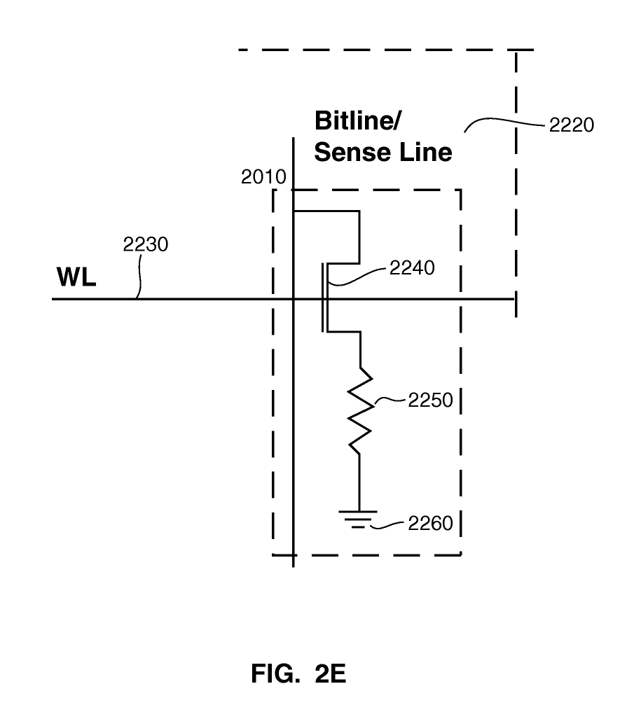

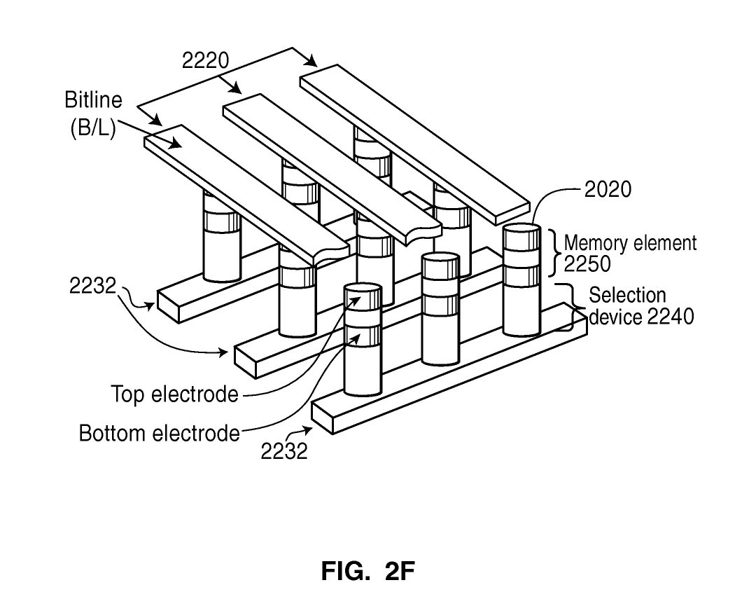

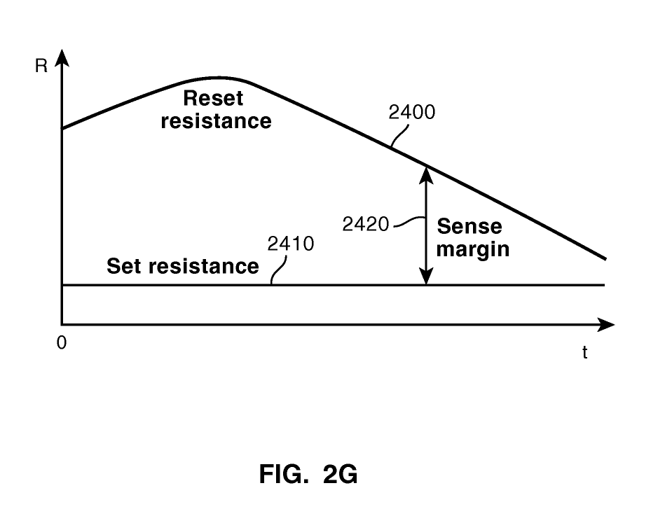

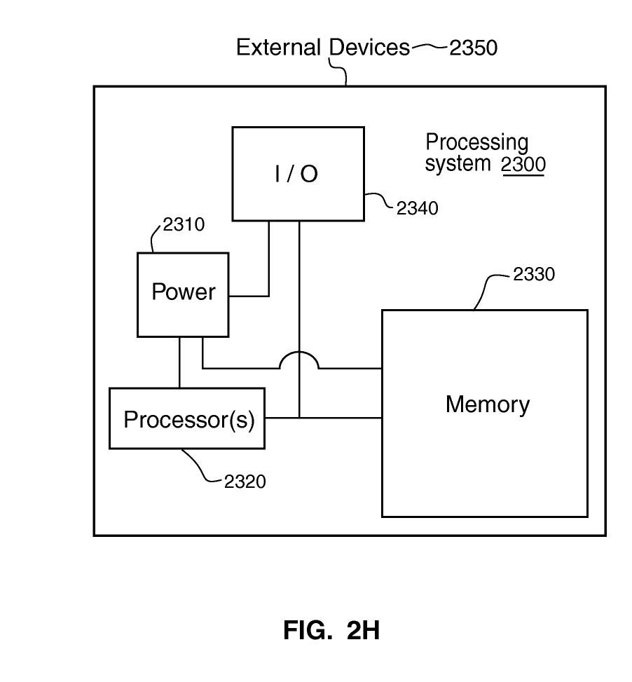

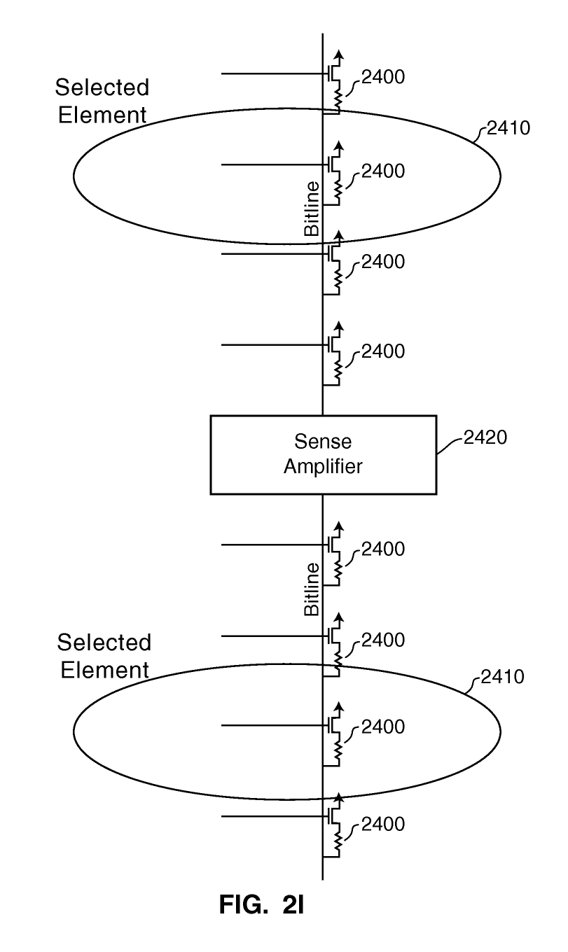

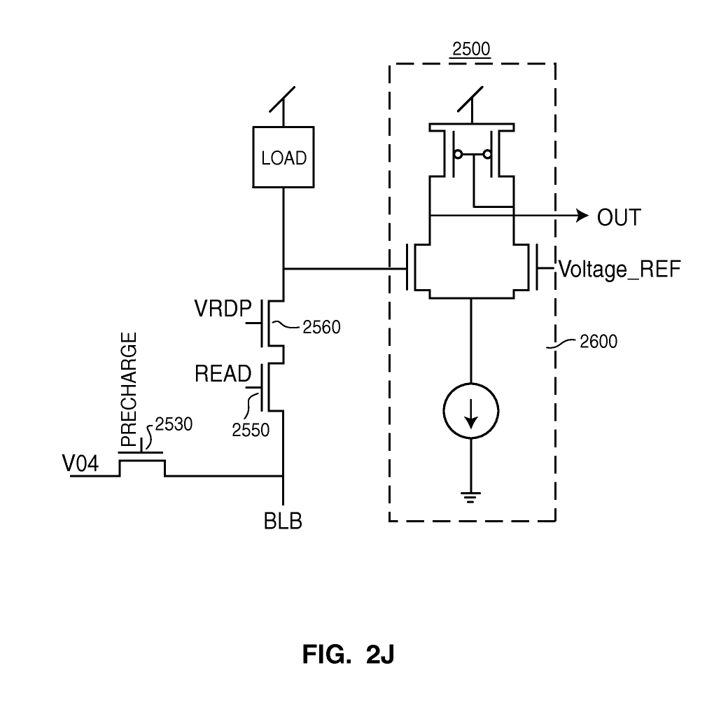

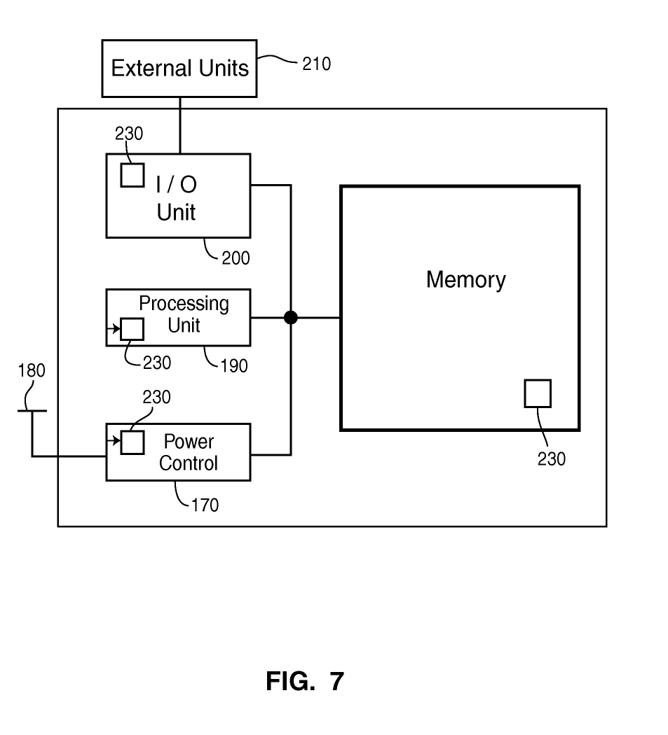

FIG. 7 shows an example of a processing system. Power control 170 manages distribution of power from a power source 180 to other components of the processing system. A processing unit 190 performs processing functions, and an I/O 200 (input/output) unit operates and manages communications with, and enables other processing system components 170, 190, 200, 220 to operate and manage communications with, external units 210. The power control 170, processing unit 190 and I/O unit 200 can also make memory access calls to a memory 220. Processing system components 170, 190, 200, 220 perform their functions based on configuration data stored by non-volatile PCM memory 230 integrated into respective processing system components 170, 190, 200, 220. PCM cells 10 in said PCM memory 230 are read using references 110 generated as disclosed herein, e.g., with respect to FIGS. 1 through 6.

Configuration data can be loaded into non-volatile memory for runtime accesses. Configuration data can be used to tune PCRAM and other component (e.g., power control 170, processing unit 190 or I/O unit 200) behavior in a design, test, or as-manufactured context. Configuration data can comprise, for example, information used by processing system components to operate external units 210; redundancy information, used to redirect accesses (read and write requests) from defective or otherwise inoperative memory cells 10 to redundant (backup) memory cells 10; trim information, generally used to alter the state of an existing topology when device features as-manufactured show variation—which can be expected within some degree of statistical distribution—that can be corrected using measures built into the device; test information used to implement test functions, e.g., for device design, design testing or as-manufactured quality assurance purposes; or to change timing (e.g., sense amp timing, or setup and hold timing in a data path), internal supply voltages, whether ECC (error correction) or other memory or other component functionality is activated, or other component operation parameters (such as word length or instruction set).

In some embodiments, a pair of reference cells 10 can be used to store a bit of information in the ordering of the corresponding stored “0” and “1” logical states. More pairs of reference cells 10 can generally store more information. If the pairing constraint is relaxed so that “0”s and “1”s can be stored anywhere within a group of reference cells 10 corresponding to a word (e.g., so that complementary logical states do not have to be adjacent to each other, or so that different logical states can be stored by different numbers of reference cells 10 in a group of reference cells 10 corresponding to a word), the ordering of said logical states can be used to store an even larger amount of information. Some constraint changes can require a more complex encoder and decoder to properly arrange storage of logical states to both conform to reference cell rules and store increased amounts of information. A single reference cell 10 pair can store, for example, a checksum (such as an XOR) for a corresponding word; or may store other information.

The amount of information encodeable in reference cells 10 corresponding to a word is proportional to the number of reference cells 10 and the combination of “0”s and “1”s stored by said reference cells 10. For example, the amount of storable information may be different if there are more “1”s than “0”s stored, rather than having an equal number of “1”s and “0”s. Generally, embodiments encoding information using ordering of logical states as stored in reference cells 10 will not have True 70 and Complement Reference Bitlines 90, as “0”s and “1”s can coexist along reference bitlines in such embodiments.

In some embodiments, reference cells 10 can be physically distributed in a memory (e.g., throughout an array); in other embodiments, they may be gathered together (e.g., along bitlines). Preferably, reference cells 10 are located to optimize timing (e.g., voltage rise and hold timing, sense amplifier 50 timing, and read timing in general) and drift matching pursuant to the particular operational characteristics of a PCM memory and component architectures thereof such as of sense amplifiers 50.

In some embodiments, after a reference 110 is generated, it is current mirrored and distributed to corresponding sense amplifiers 50.

The disclosed innovations, in various embodiments, provide one or more of at least the following advantages. However, not all of these advantages result from every one of the innovations disclosed, and this list of advantages does not limit the various claimed inventions.

approximately perfect drift tracking by read reference;

no need for coarse trimming;

reduced memory error correction requirements;

more accurate memory reads;

faster memory as a result of a reduced rate of read errors;

reduced memory area required to produce a drift-tracking reference.

According to some but not necessarily all embodiments, there is provided: A method of operating a memory comprising: when phase change memory cells within a word of data-storing phase change memory cells are written, for one or more corresponding data-storing cells within said word, contemporaneously writing a logical state other than the logical state stored by said corresponding data-storing cell to one or more corresponding reference cells accessed by the same wordline as said word; when one or more accessed cells in said word are read, generating a reference in at least partial dependence on respective resistances of said corresponding data-storing cells and said corresponding reference cells, and outputting respective logical states of said accessed cells in dependence on respective comparisons between said reference and respective outputs of said accessed cells.

According to some but not necessarily all embodiments, there is provided: A method of operating a memory comprising: when phase change memory cells within a word of data-storing phase change memory cells are written, for one or more corresponding data-storing cells within said word, contemporaneously writing a logical state other than the logical state stored by said corresponding data-storing cell to one or more corresponding reference cells; and when one or more accessed cells in said word are read, generating a reference corresponding to said logical states in at least partial dependence on respective resistances of said corresponding data-storing cells and said corresponding reference cells, and outputting respective logical states of said accessed cells in dependence on respective comparisons between said reference and respective outputs of said accessed cells.

According to some but not necessarily all embodiments, there is provided: A method of operating a memory comprising: when phase change memory cells within a word of phase change memory cells are written, for one or more corresponding data-storing cells within said word, contemporaneously writing a logical state other than the logical state stored by said corresponding data-storing cell to one or more corresponding reference cells; and when one or more accessed cells in said word are read, using the respective resistances of said reference cells to provide a reference.

According to some but not necessarily all embodiments, there is provided: A method of operating a processing system, comprising: writing multiple cells in corresponding ones of multiple words of phase change memory cells and, for one or more corresponding data-storing cells within said corresponding word, contemporaneously writing a logical state other than the logical state stored by said corresponding data-storing cell to one or more corresponding reference cells, said corresponding words and said corresponding reference cells being within a phase change memory unit and configured to store configuration data; reading accessed cells in said corresponding word, using multiple sense amplifiers, by comparing respective outputs of said accessed cells and a reference, and by outputting respective logical states of said accessed cells in dependence on said comparing; and operating external elements, using a processor and/or an input/output unit, in accordance with said configuration data, wherein said reference is generated in at least partial dependence on respective resistances of said corresponding data-storing cells and said corresponding reference cells.

According to some but not necessarily all embodiments, there is provided: A processing system, comprising: a phase change memory unit, a processor which executes programmable instruction sequences, and an input/output unit; multiple words of phase change memory cells within said phase change memory unit configured to store configuration data, multiple cells in corresponding ones of said words and multiple corresponding phase change memory reference cells configured to be written contemporaneously, said corresponding reference cells configured to be written with logical states other than the logical states stored by corresponding data-storing cells within said corresponding words, said corresponding words and said corresponding reference cells being within said phase change memory unit and configured to store configuration data; and multiple sense amplifiers configured to read accessed cells in said corresponding word by comparing respective outputs of said accessed cells and a reference, and by outputting respective logical states of said accessed cells in dependence on said comparing, wherein said reference is generated in at least partial dependence on respective resistances of said corresponding data-storing cells and said corresponding reference cells, and wherein said processor and/or said input/output unit operate external elements in accordance with said configuration data.

According to some but not necessarily all embodiments, there is provided: A memory, comprising: an array of phase change memory cells; multiple words of phase change memory cells within said array, such that multiple cells within corresponding ones of said words and multiple corresponding reference phase change memory cells are configured to be written contemporaneously, said corresponding reference cells configured to be to be accessed by the same wordline as said corresponding word and to be written with logical states other than the logical states stored by corresponding data-storing cells within said corresponding words; and multiple sense amplifiers configured to read accessed cells in said corresponding word by comparing respective outputs of said accessed cells and a reference, and by outputting respective logical states of said accessed cells in dependence on said comparing, wherein said reference is generated in at least partial dependence on respective resistances of said corresponding data-storing cells and said corresponding reference cells.

According to some but not necessarily all embodiments, there is provided: A memory, comprising: an array of phase change memory cells comprising multiple corresponding words of data-storing cells and multiple corresponding reference cells, said corresponding reference cells being configured to be to be written with logical states other than the logical states stored by corresponding data-storing cells within said corresponding words; multiple word lines, ones of said word lines connected to access rows of said cells, ones of said corresponding words comprising respective portions of said rows of cells accessed by corresponding ones of said word lines; multiple bit lines, ones of said bit lines connected to access columns of said cells; and multiple sense amplifiers configured to read accessed cells in said corresponding word by comparing respective outputs of said accessed cells and a reference, and by outputting respective logical states of said accessed cells in dependence on said comparing, wherein said reference is generated in at least partial dependence on respective resistances of said corresponding data-storing cells and said corresponding reference cells.

According to some but not necessarily all embodiments, there is provided: A memory, comprising: a processor, said processor being configured to generate memory read requests and memory write requests; an array of phase change memory cells; multiple words of phase change memory cells within said array, multiple cells within corresponding ones of said words and multiple corresponding reference phase change memory cells configured to be written contemporaneously in response to memory write requests, said corresponding reference cells being written with logical states other than the logical states stored by corresponding data-storing cells within said corresponding words; multiple sense amplifiers configured to read accessed cells in said corresponding words, in response to at least one corresponding read request designating said accessed cells, by comparing respective outputs of said accessed cells and a reference, and by outputting respective logical states of said accessed cells in dependence on said comparing, wherein said reference is generated in at least partial dependence on respective resistances of said corresponding data-storing cells and said corresponding reference cells.

According to some but not necessarily all embodiments, there is provided: Phase change memory arrays, subarrays, modules, and chips, as well as systems and devices in which phase change memory is used, wherein a reference corresponding to a pair of adjacent logical states (e.g., 0 and 1) can be generated by averaging outputs from a designated data-storing cell and a designated reference cell storing the logical complement to the logical state stored by the data-storing cell. By writing designated cells contemporaneously with words of cells that are configured to be written together, resulting references can closely track resistance changes in said words resulting from, e.g., drift and other time- and phase change material-dependent factors.

According to some but not necessarily all embodiments, there is provided: A digital processing system, comprising: a processor, said processor being configured to generate memory read requests and memory write requests; an array of phase change memory cells; multiple words of phase change memory cells within said array, multiple cells within corresponding ones of said words and multiple corresponding reference phase change memory cells configured to be written contemporaneously in response to memory write requests, said corresponding reference cells being written with logical states other than the logical states stored by corresponding data-storing cells within said corresponding words; multiple sense amplifiers configured to read accessed cells in said corresponding words, in response to at least one corresponding read request designating said accessed cells, by comparing respective outputs of said accessed cells and a reference, and by outputting respective logical states of said accessed cells in dependence on said comparing, wherein said reference is generated in at least partial dependence on respective resistances of said corresponding data-storing cells and said corresponding reference cells.

### Modifications and Variations

As will be recognized by those skilled in the art, the innovative concepts described in the present application can be modified and varied over a tremendous range of applications, and accordingly the scope of patented subject matter is not limited by any of the specific exemplary teachings given. It is intended to embrace all such alternatives, modifications and variations that fall within the spirit and broad scope of the appended claims.

In some embodiments, ones of one or more words in an array of PCM cells correspond to multiple pairs of reference PCM cells.

In some embodiments, one or more reference PCM cells correspond to (are shared by) multiple words. In such embodiments, it is preferable to write said multiple words as closely to contemporaneously as possible in order to match drift characteristics of cells in said multiple words to drift characteristics of said shared reference cells as closely as possible. This can be useful, for example, when a substantial segment—or entirety—of a PCM array is being written together, such as during testing.

In some embodiments, three or more reference PCM cells correspond to a word of PCM cells. This can be used to, for example, enhance reliability and accuracy of the resulting reference generated from the three or more reference cells.

In some embodiments, reference cells can be read differentially, i.e., by comparing a read output of a reference cell to a read output of another PCM cell. This can be used, for example, to enhance read reliability of the reference cell.

In some embodiments, reference PCM cells are not paired in high/low resistance pairs, i.e., there can be more high (or low) resistance reference cells than low (or high) resistance reference cells. This can be used to save memory area where, for example, outputs of low resistance cells are significantly more reliable (e.g., more consistent output) than outputs of high resistance cells (or vice versa).

In some embodiments, if the output current of a PCM data-storing cell is higher than I_Reference (see FIG. 1C and corresponding discussion above), then the data cell is detected to be storing a “0”; and if the output current is lower than I_Reference, then the data cell is detected to be storing a “1”. In this case, “0” corresponds to low PCM element resistance, and “1” corresponds to high PCM element resistance.

Embodiments have been disclosed hereinabove with particular numbers and configurations of wordlines, bitlines, sense amplifiers, muxes, data-storing cells, reference cells and other features. However, it will be apparent to one of ordinary skill that different arrangements of such features may be used to implement the inventions disclosed herein.

In some embodiments, bitline contents may not be strictly divided into data-storage bitlines and reference bitlines.

In some embodiments, a weighted arithmetic mean, geometric mean, or other operation producing a reference obeying the inequality described above, Ipcm0<I_Reference<Ipcm1, may be used to generate a reference (these means and other operations are referred to as “averages” for this purpose).

In some embodiments, all or substantially all cells in a word are configured to be written contemporaneously.

In some embodiments, all or substantially all cells in a word are configured to be read contemporaneously.

In some embodiments, SET and RESET pulses can be configured to reset PCM cell drift characteristics of PCM cells storing “0” and “1” logical states, i.e., without requiring a logical state transposition to reset cell drift characteristics.

In some embodiments, a transposition can be used to reset cell drift characteristics.

In some embodiments, resistance values configured to produce read outputs corresponding to those of PCM cells storing adjacent logical states with a pre-determined drift amount (e.g., no drift) are hard-coded, e.g., in resistance trims, in a PCM memory. When a corresponding word of PCM cells is written, the resistance trims are read, and a state configured to produce a read output corresponding to an average of the resistance trims' read outputs is written into one or more corresponding PCM reference cells. When the corresponding word is read, the corresponding PCM reference cells are read. If there is only one corresponding reference cell for the corresponding word, the corresponding reference cell's output is used as the reference for the corresponding word. If there are multiple corresponding reference cells, then their summed outputs are divided by the number of corresponding reference cells (or by another value resulting in a reference obeying the constraints described herein for I_Reference), and the resulting current is used as the reference for the corresponding word. In some embodiments, one or more resistance trims are hard-coded with resistances configured to output on read the average of read outputs of PCM cells storing adjacent logical states.

Additional general background, which helps to show variations and implementations, may be found in the following publications, all of which are hereby incorporated by reference: Lam, Chung. “Phase Change Memory: A Replacement or Transformational Memory Technology,” IEEE Workshop on Microelectronics and Electron Devices (WMED), c. 2011. Choi, Youngdon, et al. “A 20 nm 1.8V 8 Gb PRAM with 40 MB/s Program Bandwidth.” ISSCC 2012/Session 2/High Bandwidth DRAM & PRAM/2.5. c. 2012.

None of the description in the present application should be read as implying that any particular element, step, or function is an essential element which must be included in the claim scope: THE SCOPE OF PATENTED SUBJECT MATTER IS DEFINED ONLY BY THE ALLOWED CLAIMS. Moreover, none of these claims are intended to invoke paragraph six of 35 USC section 112 unless the exact words “means for” are followed by a participle.

Additional general background, which helps to show variations and implementations, as well as some features which can be synergistically with the inventions claimed below, may be found in the following US patent applications. All of these applications have at least some common ownership, copendency, and inventorship with the present application, and all of them are hereby incorporated by reference: U.S. Provisional Pat. Nos. 61/637,331; 61/637,496; 61/637,513; 61/637,518; 61/637,526; 61/637,533; 61/638,217; 61/694,217; 61/694,220; 61/694,221; 61/694,223; 61/694,224; 61/694,225; 61/694,228; 61/694,234; 61/694,240; 61/694,242; 61/694,243; and 61/694,245.

The claims as filed are intended to be as comprehensive as possible, and NO subject matter is intentionally relinquished, dedicated, or abandoned.

1. A method of operating a processing system, comprising:
writing multiple cells in corresponding ones of multiple words of phase change memory cells and, for one or more corresponding data-storing cells within said corresponding word, contemporaneously writing a logical state other than the logical state stored by said corresponding data-storing cell to one or more corresponding reference cells, said corresponding words and said corresponding reference cells being within a phase change memory unit and configured to store configuration data;
reading accessed cells in said corresponding word, using multiple sense amplifiers, by comparing respective outputs of said accessed cells and a reference, and by outputting respective logical states of said accessed cells in dependence on said comparing; and
operating external elements, using a processor and/or an input/output unit, in accordance with said configuration data,
wherein said reference is generated in at least partial dependence on respective resistances of said corresponding data-storing cells and said corresponding reference cells.

2. The method of operating a processing system of claim 1, wherein said configuration data is read from said phase change memory unit and loaded into volatile memory prior to said external elements being operated in accordance with said configuration data by said processor and/or said input/output unit.

3. The method of operating a processing system of claim 1, wherein said configuration data is read from said phase change memory unit and loaded into volatile memory prior to said external elements being operated in accordance with said configuration data by said processor.

4. The method of operating a processing system of claim 1, wherein said configuration data is read from said phase change memory unit and loaded into volatile memory prior to said external elements being operated in accordance with said configuration data by said input/output unit.

5. The method of operating a memory of claim 1, wherein ones of said corresponding data-storing cells correspond to multiple corresponding reference cells.

6. The method of operating a memory of claim 1, wherein said reference is an average of read outputs corresponding to said logical states of said corresponding data-storing cells and said corresponding reference cells.

7. The method of operating a memory of claim 1, wherein reference cells are not required to change phase state when written.

8. The method of operating a memory of claim 1, wherein said phase change memory reference cells are accessed by the same wordline as said corresponding word.

9. A processing system, comprising:
a phase change memory unit, a processor which executes programmable instruction sequences, and an input/output unit;
multiple words of phase change memory cells within said phase change memory unit configured to store configuration data, multiple cells in corresponding ones of said words and multiple corresponding phase change memory reference cells configured to be written contemporaneously, said corresponding reference cells configured to be written with logical states other than the logical states stored by corresponding data-storing cells within said corresponding words, said corresponding words and said corresponding reference cells being within said phase change memory unit and configured to store configuration data; and
multiple sense amplifiers configured to read accessed cells in said corresponding word by comparing respective outputs of said accessed cells and a reference, and by outputting respective logical states of said accessed cells in dependence on said comparing,
wherein said reference is generated in at least partial dependence on respective resistances of said corresponding data-storing cells and said corresponding reference cells, and
wherein said processor and/or said input/output unit operate external elements in accordance with said configuration data.

10. The processing system of claim 9, wherein said configuration data is read from said phase change memory unit and loaded into volatile memory prior to said external elements being operated in accordance with said configuration data by said processor and/or said input/output unit.

11. The processing system of claim 9, wherein said configuration data is read from said phase change memory unit and loaded into volatile memory prior to said external elements being operated in accordance with said configuration data by said processor.

12. The processing system of claim 9, wherein said configuration data is read from said phase change memory unit and loaded into volatile memory prior to said external elements being operated in accordance with said configuration data by said input/output unit.

13. The processing system of claim 9, wherein ones of said corresponding data-storing cells correspond to multiple corresponding reference cells.

14. The processing system of claim 9, wherein said reference is an average of read outputs corresponding to said logical states of said corresponding data-storing cells and said corresponding reference cells.

15. The processing system of claim 9, wherein reference cells are not required to change phase state when written.

16. The processing system of claim 9, wherein said phase change memory reference cells are accessed by the same wordline as said corresponding word.

17. A digital processing system, comprising:
a processor, said processor being configured to generate memory read requests and memory write requests;
an array of phase change memory cells;
multiple words of phase change memory cells within said array, multiple cells within corresponding ones of said words and multiple corresponding reference phase change memory cells configured to be written contemporaneously in response to memory write requests, said corresponding reference cells being written with logical states other than the logical states stored by corresponding data-storing cells within said corresponding words;
multiple sense amplifiers configured to read accessed cells in said corresponding words, in response to at least one corresponding read request designating said accessed cells, by comparing respective outputs of said accessed cells and a reference, and by outputting respective logical states of said accessed cells in dependence on said comparing,
wherein said reference is generated in at least partial dependence on respective resistances of said corresponding data-storing cells and said corresponding reference cells.

18. The digital processing system of claim 17, wherein ones of said corresponding data-storing cells correspond to multiple corresponding reference cells.

19. The digital processing system of claim 17, wherein said reference is an average of read outputs corresponding to said logical states of said corresponding data-storing cells and said corresponding reference cells.

20. The digital processing system of claim 17, wherein reference cells are not required to change phase state when written.

21. (canceled)
